(19) United States
(12) Patent Application Publication
(10) Pub. No.: US 2008/0204130 A1
(43) Pub. Date: Aug. 28, 2008

(54) Oscillator bias injector

(75) Inventors: Gerald H. Nesbit, Reston, VA (US); Forrest Wheat, Fairfax Station, VA (US)

Correspondence Address: James G. Coplit, Third Floor, 488 Main Avenue, Norwalk, CT, 06851, US

(73) Assignee: Wheat International Communications Corporation

(21) Appl. No.: 11/712,066

(22) Filed: Feb. 28, 2007

(51) Int. Cl. H03B 1/04

(52) U.S. Cl. 327/594

(57) ABSTRACT

A oscillator bias injector system for use in maritime applications in connection with a VSAT communication system including a satellite modem connected to a commercially available high power block upconverter and low noise block downconverter which are both connected to an outdoor antenna mounted on a stabilized platform, which antenna sends and receives signals from a Ku-band satellite in geosynchronous orbit. The oscillator bias injector is installed between the block upconverter and the satellite modem such that the RF signal generated by satellite modem is combined with an internally generated stabilized 10 MHz reference signal from oscillator, which summed signal is then combined with DC bias generated by an AC rectifier to thereby provide a means of interfacing a custom designed modem to the block upconverter to improve the uplink speed of the VSAT system. The improved speed allows the user to use the telecommunications system for applications that require a higher transfer rate, such as video teleconferencing and voice over Internet phones.

### BACKGROUND OF THE INVENTION

1. Field of the Invention

The present invention relates generally to single integrated device for summing the IF transmitting signal from a satellite modem (such as on a boat or ship) with a very stable external reference signal while providing the high current required to power a block upconverter.

2. Description of the Prior Art

The conventional method for summing the IF transmitting signal and reference signal is to use a two-port splitter/combiner, which does not allow for injecting high lever DC current in the system for biasing the block upconverter. The reference signal would typically be supplied with a much larger size and heavier test equipment, which is not practical for integration.

There are commercially available DC bias injectors available in the market today. However, these commercially available injectors have low current capability and do not have a wide frequency operating range. This is a critical flaw for these devices, since the bias injector must pass both the transmit IF signal and the reference signal without any significant attenuation. The transmit IF signal is typically in the 950-1450 MHz range, while the reference signal is in the 10 MHz range.

In the satellite communication arena, one of the most widely deployed systems is the VSAT (Very Small Aperture Terminal). VSAT gained its popularity due to its small antenna size and reasonable two-way data throughput capability. VSAT is commonly used by gas stations, car dealerships, department stores and maritime users for accessing the Internet. VSAT systems operate in the Ku-band frequency band. The VSAT ground terminal uses 12 GHz/14 GHz frequency range, respectively, for downlink and uplink communication with the satellite located in the geosynchronous orbit. Since the satellite modem typically operates in the 950 to 1450 MHz, it relies on a Low Noise Blockconverter (LNB) and a Block Upconverter (BUC) for the up and down frequency translation. For a VSAT ground terminal outfitted with a 1.0 meter dish and a 1 W BUC, the typical downlink and uplink speed achievable is around 512 Kbps and 128 Kbps, respectively. For the maritime community, this is a significant improvement over the 64 Kbps services offered by the Inmarsat satellites.

The 512 Kbps/128 Kbps speed is sufficient to meet most of the maritime user's need for e-mail and web browsing. However, as the demands for the other applications arise such as VoIP (voice call over the Internet) and video teleconference (VTC), the 128 Kbps uplink speed is not adequate to support all the applications simultaneously. In order to increase the uplink speed, the antenna's transmit Effective Isotropic Radiated Power (EIRP) also has to increased accordingly. Two common methods for improving EIRP are to increase the size of the antenna or to increase the transmit power of the BUC.

For the maritime users, increasing the size of the antenna is not a viable option. Most of the antennas designed for the maritime application are mounted on a 3-axis stabilized platform and are also enclosed in a tight fitting environmental sealed radome. Changing the size of the antenna would have significant impacts on both the stabilized platform and the radome. In addition, many of the ships may not have space to accommodate the larger size antenna system. The most viable method for increasing the transmit EIRP is to use a higher power BUC.

In most of the VSAT system, the modem is typically integrated with its own BUC for the uplink operation and both the modem and the BUC are tested & offered as a package in the satellite network. If one decides to use vendor A modem with vendor B BUC, then there will be technical interface issues to be resolved. For an example, there is a significant impacts to the satellite modem when the system requirement changes the BUC from 1 W to a much higher power unit, such as a 4 W unit.

In a typical VSAT system, the satellite modem is interconnected to the BUC using a length of flexible coaxial cable. The modem supplies both the IF signal and the DC power to the BUC, via a length of flexible coaxial cable. The typical power consumption for a 1 W BUC is approximately 18 Watts, whereas, the power consumption for a 4 W BUC is approximately 53 Watts. As mentioned above, the modem typically supplies the necessary DC power to the BUC. A modem that is designed originally to interface with only a 1 W BUC will not have the excess capacity to meet the power consumption requirement of a 4 W BUC. In addition to the increased power consumption, the 4 W BUC also requires a low phase noise and stable external 10 MHz reference signal coming from the modem.

The satellite modem is not a piece of equipment that is readily available commercially off-the-shelf and can be used in a proprietary network. Typically, the satellite service providers custom designed their modems so that it will only operate in their network. With the constraint of not able to change out the satellite modem to match the requirement of a higher power BUC, an external device is needed to fulfill the needs.

Of course, it should be appreciated that satellite communications systems used in connection with GPS receivers and the like have long been known in the prior art. For example, U.S. Pat. No. 6,400,314, which issued to Krasner on Jun. 4, 2002 for “GPS receiver utilizing a communication link” related U.S. Pat. No. 6,064,336, which issued to Krasner on May 16, 2000 for “GPS receiver utilizing a communication link” both disclose the use of a precision carrier frequency signal to calibrate the local oscillator of a GPS receiver which is used to acquire GPS signals such that the output of the local oscillator, which is used to acquire GPS signals, is modified by a reference signal generated from the precision carrier frequency signal. The GPS receiver locks to this precision carrier frequency signal and generates the reference signal.

In a related patent, namely U.S. Pat. No. 6,133,871, which issued on Oct. 17, 2000 for “GPS receiver having power management,” Krasner also discloses a GPS receiver including an antenna which receives GPS signals at an RF frequency from in view satellites; a downconverter coupled to the antenna for reducing the RF frequency of the received GPS signals to an intermediate frequency; a digitizer coupled to the downconverter and sampling the IF GPS signals at a predetermined rate to produce sampled IF GPS signals; a memory coupled to the digitizer storing the sampled IF GPS signals; and a digital signal processor coupled to the memory and operating under stored instructions thereby performing operations on the sampled IF GPS signals to provide pseudorange information.

The combination of a GPS and a communications system was proposed by Krasner in U.S. Pat. No. 6,002,363, which issued on Dec. 14, 1999 for “Combined GPS positioning system and communications system utilizing shared circuitry.” This earlier patent discloses a combined GPS and communication system including an antenna for receiving data representative of GPS signals, a frequency converter coupled to the antenna, a frequency synthesizer coupled to the frequency converter, an analog to digital converter coupled to the frequency converter and a processor coupled to the frequency converter. The processor processes the data representative of GPS signals to determine a pseudorange based on the data representative of GPS signals. And in an earlier patent, Krasner disclosed a GPS receiver and means for processing the signal received thereby to provide pseudorange information. Specifically, U.S. Pat. No. 5,663,734, which issued to Krasner on Sep. 2, 1997 for “GPS receiver and method for processing GPS signals” discloses a GPS receiver including an antenna which receives GPS signals at an RF frequency from in view satellites; a downconverter coupled to the antenna for reducing the RF frequency of the received GPS signals to an intermediate frequency; a digitizer coupled to the downconverter and sampling the IF GPS signals at a predetermined rate to produce sampled IF GPS signals; a memory coupled to the digitizer storing the sampled IF GPS signals; and a digital signal processor coupled to the memory and operating under stored instructions thereby performing Fast Fourier Transform operations on the sampled IF GPS signals to provide pseudorange information.

The use of global positioning systems for vehicle tracking has been known for over a decade. For example, U.S. Pat. No. 5,225,842, which issued to Brown, et al. on Jul. 6, 1993 for “Vehicle tracking system employing global positioning system (GPS) satellites” discloses a tracking system including a sensor mounted on each object to be tracked, a communication link, a workstation, and a GPS reference receiver. The sensor operates autonomously following initialization by an external network management facility to sequence through the visible GPS satellites, making pseudo range and delta range or time difference and frequency difference measurements.

An even earlier example of a receiver for a GPS is shown in U.S. Pat. No. 5,101,416, which issued to Fenton, et al. on Mar. 31, 1992 for “Multi-channel digital receiver for global positioning system,” which discloses a receiver for pseudorandom noise encoded signals consisting of a sampling circuit and multiple channel circuits, with each channel circuit including a carrier and code synchronizing circuit and multiple digital correlators with dynamically adjustable code delay spacing.

There are also numerous references in the prior art to satellite communications systems. For example, U.S. Pat. No. 5,995,812, which issued to Soleimani, et al. on Nov. 30, 1999 for “VSAT frequency source using direct digital synthesizer” discloses a frequency generation device for a satellite communication system composed of a central hub station and a number of remote units which contain a single synthesizer located in an indoor unit. for modulating the baseband signal and conveying the modulated signal to an outdoor unit for communication between the remote unit and the central hub.

Other examples of satellite communications systems abound. For example, U.S. Pat. No. 6,091,780, which issued to Sointula on Jul. 18, 2000 for “Transmitting and receiving radio signals” discloses a system for transmitting a radio signal in a satellite mobile telephone by generating a digital input signal which is processed in combination with a digital modulating signal to produce a digital intermediate signal which is then converted into an analog intermediate signal and said analog intermediate signal is processed in combination with an analog modulating signal to produce a radio frequency output signal. A related patent to Sointula, namely U.S. Pat. No. 6,347,121, which issued on Feb. 12, 2002 for “Transmitting and receiving radio signals,” also discloses a system for transmitting a radio signal in a satellite mobile telephone by generating a digital input signal which is processed in combination with a digital modulating signal to produce a digital intermediate signal. The digital intermediate signal is converted into an analog intermediate signal and said analog intermediate signal is processed in combination with an analog modulating signal to produce a radio frequency output signal.

Small aperture terminals used in connection with satellite communications are also well known in the art. In U.S. Pat. No. 5,790,601, which issued to Corrigan, III, et al. on Aug. 4, 1998 for “Low cost very small aperture satellite terminal” a remote ground terminal transmitter is disclosed for transmitting a modulated data signal having a constant envelope amplitude comprising a source of data signals, a modulator for providing a carrier signal, receiving a data signal from the source of data signals, and modulating the carrier signal with the received data signal so as to produce a constant envelope minimum shift key modulation signal. Similarly, U.S. Pat. No. 5,559,809, which issued to Jeon, et al. on Sep. 24, 1996 for “Transmit block up-converter for very small aperture terminal remote station” discloses a transmit block up-converter, including a demultiplexer, for processing a multiplexed signal including a transmit IF signal, a reference frequency signal, a switching signal, a level signal and a constant-current signal, which is provided through one transmitting line from an indoor unit in the very small aperture terminal remote station for satellite communication.

Even earlier prior art references exist relative to satellite communications systems. For example, U.S. Pat. No. 5,027,430, which issued to Yamauchi, et al. on Jun. 25, 1991 for “Outdoor unit low noise converter for satellite broadcast reception use” discloses an outdoor unit low noise converter for satellite broadcast reception use and 2-band low noise converter capable of receiving a plurality of bands in one converter.

Recent patent applications discuss the U.S. Patent App. No. 20030185168 filed in the name of Tung and published on Oct. 2, 2003 for “Topology of frequency converting blocks of wireless LAN access point” discloses a system consisting of an indoor unit including an access point in connection with the indoor wired network through a network cable, a down converter reducing radio frequency outputted by the access point to intermediate frequency and a DC injector used to connect intermediate frequency IF with the DC power, and an outdoor unit including an up converter connected with the output interface of the DC injector by a coaxial cable and used to lift intermediate frequency IF to radio frequency RF and a booster boosting radio frequency RF of the up converter for output.

In another recently filed application, the use of a bi-directional RF converter/amplifier for converting and amplifying an RF signal is disclosed. Specifically, U.S. patent App. No. 20030104780 filed in the name of Young and published on Jun. 5, 2003 for “Pole mounted bi-directional RF converter amplifier and system” discloses a remote mounted radio frequency bi-directional converter/amplifier device that connects to a half-duplex radio transceiver that converts and amplifies the RF signals to and from that signal to a different radio band.

### SUMMARY OF THE INVENTION

Against the foregoing background, it is a primary object of the present invention to provide a single integrated device for summing the IF transmitting signal from a satellite modem.

It is another object of the present invention to provide such an integrated device that includes a very stable reference signal.

It is yet another object of the present invention to provide such an integrated device that provides the high current required to power a block upconverter.

It is still another object of the present invention to provide such an integrated device that may be used in a maritime environment.

It is another object of the present invention to provide such an integrated device that provides sufficient bandwith for applications such as voice call over the Internet and video teleconferencing.

It is another object of the present invention to provide such an integrated device that utilizes a standard antenna design for maritime application enclosed within a tight fitting environmentally sealed radome for protection against the harsh saltwater environment.

It is still another object of the present invention to provide such an integrated device which is relatively simple to install and maintain.

It is yet another object of the present invention to provide such an integrated device which provides a simple means of interfacing a custom designed modem to a commercially available block upconverter to improve the uplink speed of a VSAT system.

To the accomplishments of the foregoing objects and advantages, the present invention, in brief summary, comprises an oscillator bias injector system for use in maritime applications in connection with a VSAT communication system including a satellite modem connected to a commercially available high power block upconverter and low noise block downconverter which are both connected to an outdoor antenna mounted on a stabilized platform, which antenna sends and receives signals from a Ku-band satellite in geosynchronous orbit. The oscillator bias injector is installed between the block upconverter and the satellite modem such that the RF signal generated by satellite modem is combined with an internally generated stabilized 10 MHz reference signal from oscillator, which summed signal is then combined with DC bias generated by an AC rectifier to thereby provide a means of interfacing a custom designed modem to the block upconverter to improve the uplink speed of the VSAT system. The improved speed allows the user to use the telecommunications system for applications that require a higher transfer rate, such as video teleconferencing and voice over Internet phones

### BRIEF DESCRIPTION OF THE DRAWINGS

The foregoing and still other objects and advantages of the present invention will be more apparent from the detailed explanation of the preferred embodiments of the invention in connection with the accompanying drawings, wherein:

FIG. 1 is a simplified block diagram of a traditional VSAT system and applications therefor.

FIG. 2 is a simplified block diagram of a VSAT system and applications therefor incorporating the oscillator bias injector of the present invention.

FIG. 3 is a functional block diagram showing the oscillator bias injector of the present invention.

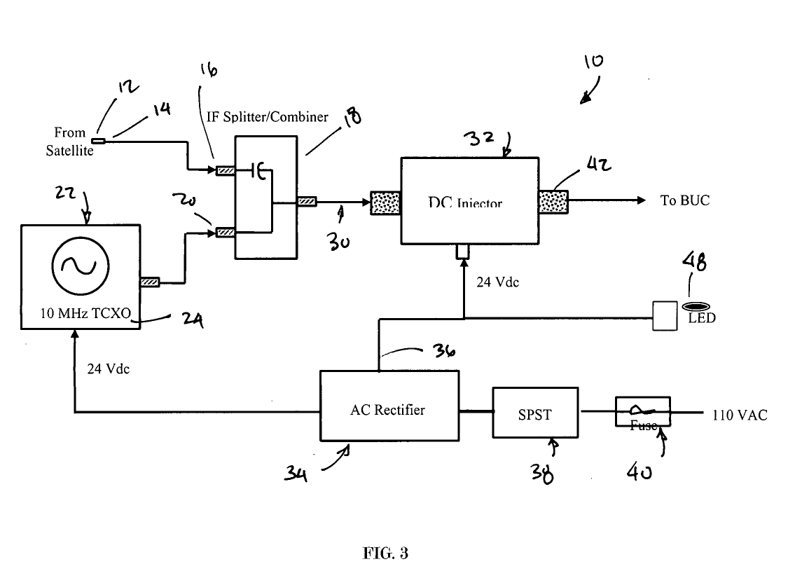

### BRIEF DESCRIPTION OF THE PREFERRED EMBODIMENTS

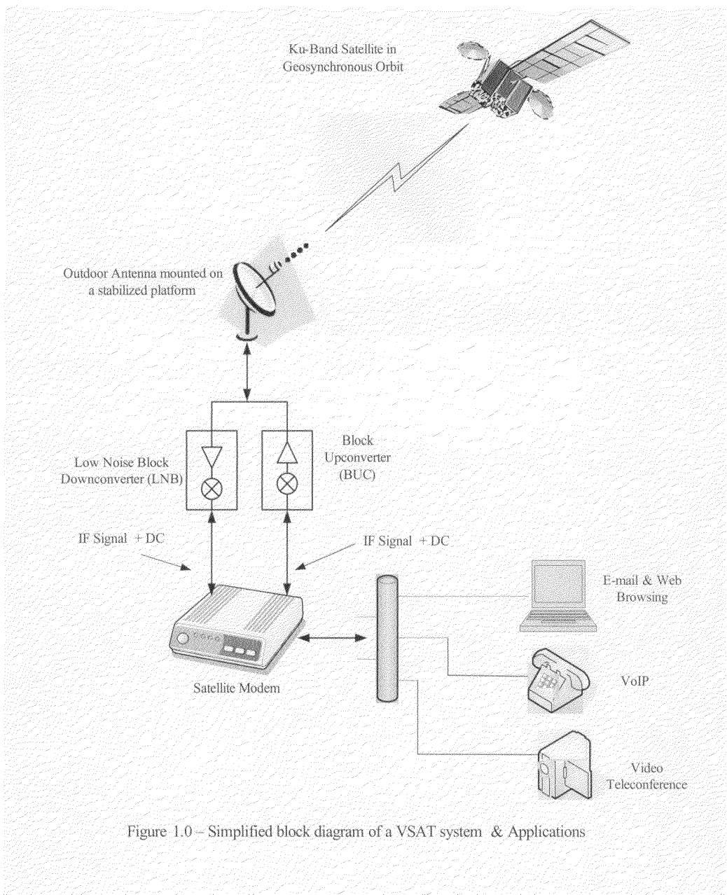

Referring to the drawings and, in particular, to FIG. 1 thereof, the oscillator bias injector of the present invention is provided and is referred to generally by reference numeral 10. The system 10 comprises a satellite modem 12 having an RF output 14, which is electrically connected to the DC block port 16 of an IF splitter/combiner 18. A straight thru port 20 on the IF splitter/combiner 18 is electrically connected to an oscillator 22, which device generates a 10 MHz reference signal 24. The satellite modem 12 is adapted to receive an RF signal 26 from a satellite 28, which RF signal 26 is summed with the 10 MHz reference signal 24 in the IF splitter/combiner to generate a summed signal 30. The summed signal 30 is then sent to a DC injector 32 which is electrically connected to the IF splitter/combiner 18.

An AC rectifier 34 is also included for providing DC bias 36 to the components of the oscillator bias injector system 10 of the present invention. The AC rectifier 34 converts 110 volts AC to 24 volts DC, and has an output power capability of 100 watts. The output voltage from the AC rectifier 34 can be controlled by a single-pole-single-throw (SPST) switch 38 and is also protected by fuse 40. The DC bias 36 from the AC rectifier 34 is electrically connected to the bias port 42 of the DC injector 32. The RF signal 26 and the 10 MHz reference signal 24 and the DC bias 36 are then all combined in the DC injector 32 before it is send to a block upconverter (BUC) 44 via flexible coaxial cable 46. An LED display 48 may also be provided on the front panel of the oscillator bias injector 10 of the present invention to indicate the power-on status of the system.

It should be understood that it is critical that the DC bias 36 from the satellite modem 12 is terminated at the DC injector 32 or it may damage the oscillator 22. In addition to causing potential damages to the oscillator 22, the DC bias 36 from the modem 12 may also interfere with the intended bias to the BUC.

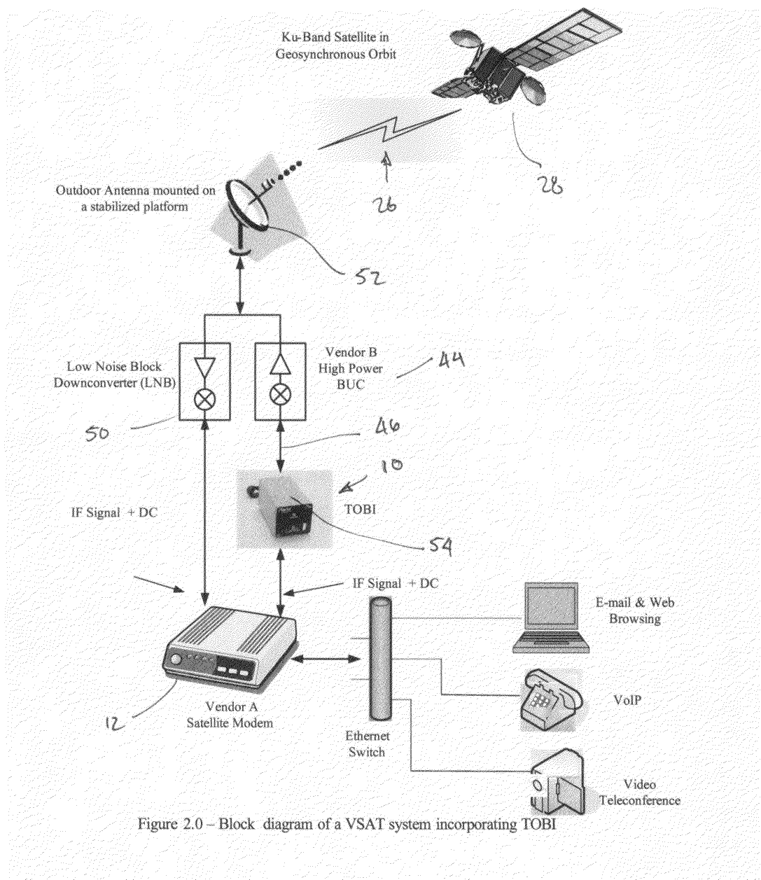

In actual operation, as illustrated in FIG. 2, the oscillator bias injector 10 of the present invention is incorporated within a VSAT communication system including a satellite modem 12 connected to a commercially available high power block upconverter 44 and to a commercially available low noise block downconverter 50 which are both connected to an outdoor antenna 52 mounted on a stabilized platform, which antenna sends and receives signals from a Ku-band satellite 28 in geosynchronous orbit. The oscillator bias injector 10 is electrically connected between the block upconverter 44 and the satellite modem 12 such that the RF signal 26 generated by satellite modem 12 is combined with an internally generated stabilized 10 MHz reference signal 24 from oscillator 22, which summed signal 30 is then combined with DC bias 36 generated by AC rectifier 34 to thereby provide a means of interfacing a custom designed modem to the block upconverter 44 to improve the uplink speed of the VSAT system. The improved speed allows the user to use the telecommunications system for applications that require a higher transfer rate, such as video teleconferencing and voice over Internet phones. As illustrated, the oscillator bias injector 10 may be housed within a protective casing 54.

Having thus described the invention with particular reference to the preferred forms thereof, it will be obvious that various changes and modifications can be made therein without departing from the spirit and scope of the present invention as defined by the appended claims.

Wherefore, we claim:

1. An oscillator bias injector system for use in maritime applications to improve the uplink speed in a VSAT structure including a high power block upconverter and a low noise block downconverter which are both connected to an antenna for receiving and sending signals to a satellite, said system comprising a satellite modem and oscillator electrically connected with an IF splitter/combiner which, in turn, is electrically connected to a DC injector, wherein said DC injector is further electronically connected to said block upconverter, and wherein said oscillator and said DC injector are powered by a an AC rectifier.

2. The oscillator bias injector system of claim 1, wherein said oscillator generates a 10 MHz reference signal.

3. The oscillator bias injector system of claim 2, wherein said satellite modem generates an RF signal.

4. The oscillator bias injector system of claim 3, wherein said IF splitter/combiner is adapted to receive said 10 MHz reference signal and said RF signal and combine them into a summed signal.

5. The oscillator bias injector system of claim 4, wherein said satellite modem produces DC bias, and wherein said DC injector operates to terminate said DC bias so as to prevent damage to said oscillator.

6. The oscillator bias injector system of claim 5, further including a power supply operating at 110 volts AC, and wherein said AC rectifier includes means to convert said 110 volts AC to 24 volts DC with an output power of 100 watts.

7. The oscillator bias injector system of claim 6, wherein said AC rectifier is controlled by a single-pole, single-throw switch.

8. The oscillator bias injector system of claim 6, wherein said AC rectifier is protected by a fuse.

9. The oscillator bias injector system of claim 6, wherein said AC rectifier is electrically connected to said DC injector and to said oscillator, and further wherein said DC injector operates to combine said 24 volts DC with said summed signal and to send said combined 24 volts DC and said summed signal to said block upconverter.

10. The oscillator bias injector system of claim 9, wherein said DC injector and said block upconverter are electrically connected by means of flexible coaxial cable.

11. The oscillator bias injector system of claim 1, further including an LED display to indicate the powered status of said system.

12. The oscillator bias injector system of claim 1, wherein said IF splitter/combiner, said DC injector and said AC rectifier are housed within a protective casing.

13. An oscillator bias injector system for use in maritime applications to improve the uplink speed in a VSAT structure including a high power block upconverter and a low noise block downconverter which are both connected to an antenna for receiving and sending signals to a satellite, said system comprising:
a satellite modem which operates to generate an RF signal;
an oscillator for generating a 10 MHz reference signal;
an IF splitter/combiner electrically connected to said satellite modem and said oscillator and adapted to receive said RF signal and said 10 MHz reference signal and combine them into a summed signal;
an AC rectifier including means to convert 110 volts AC to 24 volts DC with an output power of 100 watts, wherein said AC rectifier is controlled by a single-pole, single-throw switch and is protected by a fuse; and
a DC injector electrically connected to said IF splitter/combiner and said AC rectifier, wherein said DC injector operates to combine said 24 volts DC with said summed signal and to send said combined 24 volts DC and said summed signal to said block upconverter, and further wherein said DC injector operates to terminate said any DC bias produced by said AC rectifier or said satellite modem so as to prevent damage to said oscillator, and wherein said DC injector is further electronically connected to said block upconverter.

14. The oscillator bias injector system of claim 13, further including an LED display to indicate the powered status of said system.

15. The oscillator bias injector system of claim 13, wherein said IF splitter/combiner, said DC injector and said AC rectifier are housed within a protective casing.

16. A method for improving the uplink speed in a VSAT structure in a maritime application including a high power block upconverter and a low noise block downconverter which are both connected to an antenna for receiving and sending signals to a satellite, said method comprising the steps of:
providing an oscillator bias injector system comprising a satellite modem and oscillator for generating a 10 MHz reference signal, said oscillator being electrically connected with an IF splitter/combiner which, in turn, is electrically connected to a DC injector, wherein said DC injector is further electronically connected to said block upconverter, and wherein said oscillator and said DC injector are powered by a an AC rectifier;
sending and receiving RF signals from said satellite using said satellite modem;
summing said RF signal from said satellite modem and said 10 MHz reference signal using said IF splitter/combiner;
generating DC bias by said AC rectifier;
combining said summed RF signal and 10 MHz reference signal with said DC bias; and
sending said combined signal to said block upconverter.
